(19) United States
(12) Patent Application Publication
(10) Pub. No.: US 2020/0336128 A1
(43) Pub. Date: Oct. 22, 2020

(54) QUARTZ CRYSTAL DEVICE AND METHOD FOR MANUFACTURING THE SAME

(71) Applicant: NIHON DEMPA KOGYO CO., LTD., Tokyo (JP)

(72) Inventors: Tomonori ABE, Saitama (JP); Takafumi SAITOH, Saitama (JP)

(73) Assignee: NIHON DEMPA KOGYO CO., LTD., Tokyo (JP)

(21) Appl. No.: 16/831,768

(22) Filed: Mar. 26, 2020

(30) Foreign Application Priority Data
Apr. 19, 2019 (JP) 2019-079873

(51) Int. Cl. H03H 9/09; H03H 3/02; H03H 9/19

(52) U.S. Cl. CPC H03H 9/09; H03H 9/19; H03H 3/02

(57) ABSTRACT

A quartz crystal device includes a package and a pedestal. The package includes a base plate on which a metal pattern is provided. A crystal element is mounted to the pedestal. The pedestal is adhered to the metal pattern with a conductive adhesive. The pedestal includes a main body, two connection portions, two clearance portions, a mounting portion, and arm portions. The two connection portions are provided along long sides of the main body. The two clearance portions are provided along the long sides. The arm portions are provided on four corners of the main body to connect the mounting portion to the connection portions. The connection portion of the pedestal and the metal pattern are adhered with the conductive adhesive dividedly applied to a plurality of positions on the metal pattern of the base plate and subsequently integrated.

### CROSS-REFERENCE TO RELATED APPLICATIONS

This application claims the priority benefit of Japanese Patent Application No. 2019-079873, filed on Apr. 19, 2019. The entirety of the above-mentioned patent application is hereby incorporated by reference herein and made a part of this specification.

### TECHNICAL FIELD

This disclosure relates to a quartz crystal device and a method for manufacturing the same, especially, a quartz crystal device that reduces a vibration influence so as to improve a vibration resistance characteristic, so as to ensure an excellent phase noise characteristic and a method for manufacturing the same.

### DESCRIPTION OF THE RELATED ART

### Description of Prior Arts

In a conventional quartz crystal device, a configuration where a pedestal (crystal pedestal) mainly formed of crystal is employed is known as a configuration that reduces an influence of a vibration from a package and an outside of the package to a crystal element.

In a quartz crystal device where a pedestal is used, metal electrodes disposed in connection portions of the pedestal are adhered to a base plate of a package with, for example, a conductive adhesive in some cases.

### Related Art

Related prior arts are disclosed in Japanese Patent No. 3017750 “CRYSTAL UNIT,” Japanese Patent No. 4715252 “PIEZOELECTRIC RESONATOR,” and Japanese Unexamined Patent Application Publication No. 2013-098678 “CRYSTAL UNIT.”

Japanese Patent No. 3017750 discloses a crystal unit that includes a holding blank having a depressed portion formed at a position for mounting a vibration crystal element. The crystal unit reliably excites the vibration crystal element in a clearance formed by the depressed portion and reduces a stress due to a heat in a longitudinal direction of an excitation crystal element.

Japanese Patent No. 4715252 discloses a piezoelectric resonator that includes a spring portion including a clearance to reduce the thermal expansion influence in a base plate.

Japanese Unexamined Patent Application Publication No. 2013-098678 discloses a crystal unit configured to suppress deformation of a crystal element in association with a temperature change and ensure the excellent frequency/temperature characteristics.

However, the conventional crystal pedestal of the quartz crystal device has a problem that a vibration from outside influences the crystal element and the vibration deteriorates a phase noise characteristic.

Japanese Patent No. 3017750, Japanese Patent No. 4715252, and Japanese Unexamined Patent Application Publication No. 2013-098678 do not include descriptions regarding a pedestal configured to more easily absorb a vibration from outside, or application of an adhesive when the pedestal to which a crystal element is mounted is adhered to a base plate.

A need thus exists for a quartz crystal device and a method for manufacturing the same which are not susceptible to the drawback mentioned above.

### SUMMARY

According to an aspect of this disclosure, there is provided a quartz crystal device that includes a package and a pedestal. The package includes a base plate on which a metal pattern is provided. A crystal element is mounted to the pedestal. The pedestal is adhered to the metal pattern with a conductive adhesive. The pedestal includes a main body, two connection portions, two clearance portions, a mounting portion, and arm portions. The two connection portions are provided along long sides of the main body and contact the base plate. The two clearance portions are provided along the long sides inside the main body with respect to the connection portions. The crystal element is mounted to the mounting portion. The mounting portion is located between the two clearance portions. The arm portions are provided on four corners of the main body to connect the mounting portion to the connection portions. The connection portion of the pedestal and the metal pattern are adhered with the conductive adhesive dividedly applied to a plurality of positions on the metal pattern of the base plate and subsequently integrated.

### BRIEF DESCRIPTION OF THE DRAWINGS

The foregoing and additional features and characteristics of this disclosure will become more apparent from the following detailed description considered with reference to the accompanying drawings, wherein:

FIG. 1 is an explanatory drawing illustrating a front surface of the pedestal;

FIG. 2 is an explanatory drawing illustrating a long side surface of the pedestal;

FIG. 3 is an explanatory drawing illustrating a short side surface of the pedestal;

FIG. 4 is an explanatory drawing illustrating an application pattern of an adhesion at one point on each side;

FIG. 5 is an explanatory drawing illustrating a front surface of a quartz crystal device formed by the adhesion at one point on each side;

FIG. 6 is an explanatory drawing illustrating an application pattern of an adhesion at two points on each side;

FIG. 7 is an explanatory drawing illustrating a front surface of the quartz crystal device formed by the adhesion at two points on each side;

FIG. 8 is an explanatory drawing illustrating an application pattern of an adhesion at three points on each side;

FIG. 9 is an explanatory drawing illustrating a front surface of the quartz crystal device formed by the adhesion at three points on each side;

FIG. 10 is an explanatory drawing illustrating vibration directions used for evaluating vibration resistance characteristics; and

FIG. 11 is a diagram illustrating evaluation results of the vibration resistance characteristics.

### DETAILED DESCRIPTION

The following describes an embodiment of the disclosure with reference to the drawings.

### Outline of Embodiment

A quartz crystal device according to the embodiment of the disclosure is configured such that a crystal element (vibrating element) is mounted to a pedestal configured to easily absorb a vibration, and electrodes of the pedestal are connected to a base plate of a package made of, for example, ceramic with a conductive adhesive. After the conductive adhesive is dispersedly (dividedly) applied to a plurality of positions on a metal pattern of the base plate, the electrodes of the pedestal and electrodes on the base plate side are connected in a state where the respective portions are continuously integrated. The pedestal absorbs a vibration from outside. Additionally, increase of an application amount of the soft conductive adhesive ensures a damper (vibration absorption) effect, and therefore the quartz crystal device further improves a vibration resistance characteristic to ensure an excellent phase noise characteristic.

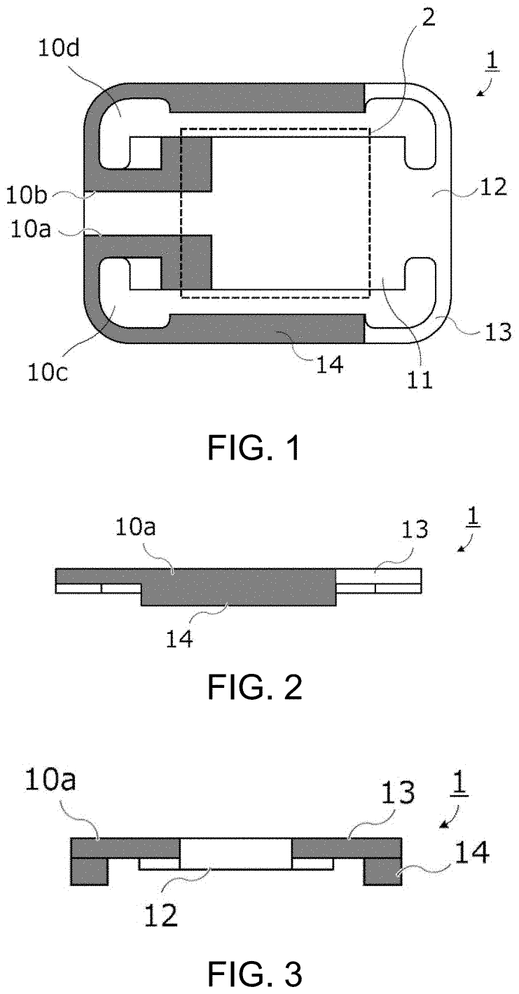

Further, a method for manufacturing the quartz crystal device according to the embodiment of the disclosure is configured such that after the crystal element is mounted to the pedestal configured to easily absorb a vibration, and the conductive adhesive is dividedly applied to a plurality of positions on the metal pattern formed on the base plate of the package made of, for example, ceramic, the pedestal is mounted onto the metal pattern to integrate the divided conductive adhesives, and the pedestal and the metal pattern are adhered with the integrated conductive adhesive. The pedestal absorbs a vibration from outside. Additionally, increase of the application amount of the soft conductive adhesive provides the damper effect, and therefore the method further improves the vibration resistance characteristic to ensure the excellent phase noise characteristic.

[Pedestal of Quartz Crystal Device According to Embodiment: FIG. 1 to FIG. 3]

First, the pedestal used in the quartz crystal device according to the embodiment of the disclosure is described using FIG. 1 to FIG. 3. FIG. 1 is an explanatory drawing illustrating a front surface of the pedestal. FIG. 2 is an explanatory drawing illustrating a long side surface of the pedestal. FIG. 3 is an explanatory drawing illustrating a short side surface of the pedestal.

As illustrated in FIG. 1, a pedestal 1 includes clearance portions 10c and 10d, a central mounting portion 11, an extended portion 12, arm portions 13, and connection portions 14. The clearance portions 10c and 10d are internally formed along two long sides of a main body. The mounting portion 11 is located between the clearance portions 10c and 10d, and a crystal element 2 is mounted thereto. The extended portion 12 extends from a short side of the mounting portion 11 to a main body short side. The arm portion 13 is curved in a circular arc shape on four corner portions. The connection portion 14 is disposed on a long side of the mounting portion 11 in parallel and is connected to an electrode formed on a base plate (bottom surface) 3 of the package.

In the pedestal 1, electrode patterns 10a and 10b are formed.

Specifically, the electrode patterns 10a and 10b have square-shaped patterns formed on a front surface of the mounting portion 11, and the square-shaped patterns are connected to excitation electrodes of the crystal element 2. The electrode patterns 10a and 10b are extracted to the extended portion 12 side next to the square-shaped patterns to be formed up to right side end portions of the connection portions 14 via the arm portions 13.

Further, the electrode patterns 10a and 10b are also formed on side surfaces and back surfaces of the arm portions 13 and side surfaces and back surfaces of the connection portions 14.

Further, as illustrated in FIG. 2 and FIG. 3, thicknesses of the respective portions are formed as follows. The connection portion 14 is the thickest, the mounting portion 11 is the second thickest, and the arm portion 13 is the thinnest.

This formation causes a state where only the connection portion 14 is connected to the base plate 3 of the package, and the mounting portion 11 and the arm portion 13 are disposed apart from the base plate 3.

Further, the arm portion 13 is formed to have a width narrower and thinner than the connection portion 14 and is configured to be bent and easily deformed.

Thus, in the configuration, even when a vibration is applied to the connection portion 14 from outside, the arm portion 13 and the extended portion 12 can absorb and reduce the vibration. This reduces an influence on the crystal element 2 mounted to the mounting portion 11.

Note that, while the thicknesses of the respective portions of the pedestal 1 are configured such that the connection portion 14>the mounting portion 11>the arm portion 13 here, and the thicknesses of the connection portion 14 and the mounting portion 11 may be configured to be the same, that is, the thicknesses of the respective portions of the pedestal 1 may be configured such that the connection portion 14=the mounting portion 11>the arm portion 13.

In the case where the pedestal 1 is formed in this manner, a step portion is disposed on the base plate 3 of the package, and the connection portion 14 of the pedestal 1 is mounted onto the step portion, thus ensuring that the mounting portion 11 is disposed apart from the base plate 3 so as not to contact the base plate 3.

[Influence of Conductive Adhesive]

When the quartz crystal device is installed to the base plate 3 of, for example, the ceramic package, electrodes of the pedestal 1 are connected to a metal pattern formed on the base plate 3 of the package with a conductive adhesive.

That is, since the conductive adhesive is located between the base plate 3 of the package, to which a vibration from outside is directly transmitted, and the pedestal 1, and moreover, the conductive adhesive is made of a soft material, the conductive adhesive is expected to function as a buffer.

Therefore, the number of points to which the conductive adhesive was applied and an application amount were changed to evaluate its vibration resistance characteristic. Here, a silicone-based adhesive was employed as the conductive adhesive.

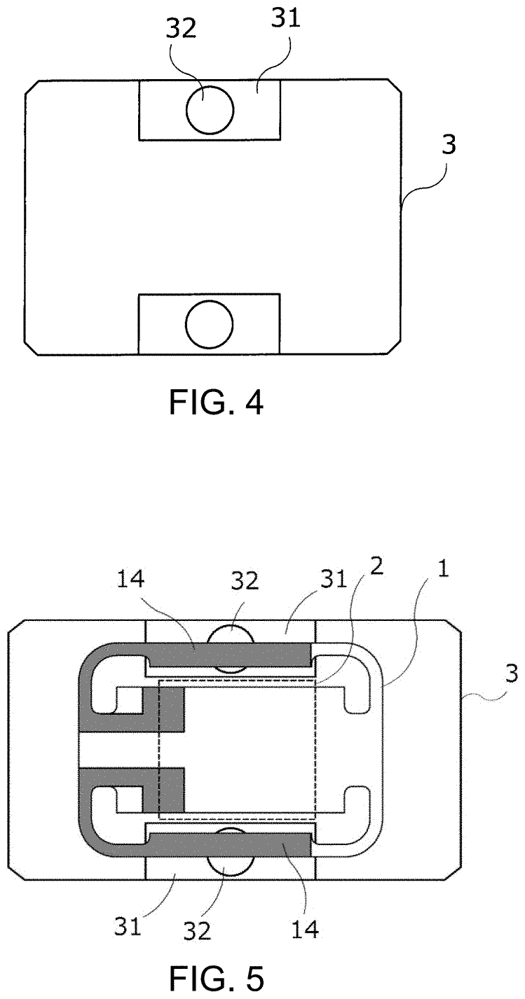

As the pedestal 1, a pedestal that had an outside dimension of a length 1.2 mm×a width 0.85 mm and included the connection portion 14 having a length of approximately 0.64 mm and a width of approximately 0.12 mm was employed.

[Application Pattern of Conductive Adhesive: FIG. 4 to FIG. 9]

Application patterns to be evaluated and the quartz crystal device adhered in the respective application patterns are described using FIG. 4 to FIG. 9.

[Adhesion at One Point on Each Side: FIG. 4 and FIG. 5] FIG. 4 is an explanatory drawing illustrating an application pattern of an adhesion at one point on each side. FIG. 5 is an explanatory drawing illustrating a front surface of the quartz crystal device formed by the adhesion at one point on each side.

As illustrated in FIG. 4 and FIG. 5, in the adhesion at one point on each side, a conductive adhesive 32 is applied to one point on a metal pattern 31 formed along each long side on the base plate 3 to mount the pedestal 1, so as to form the quartz crystal device. Note that, in the experiments, a quartz crystal device where the step portions are disposed on the base plate 3 and the metal patterns 31 are formed onto the step portions was employed.

A method of the adhesion at one point on each side is typically used, and the conductive adhesive 32 is applied to the approximate center of the metal pattern 31.

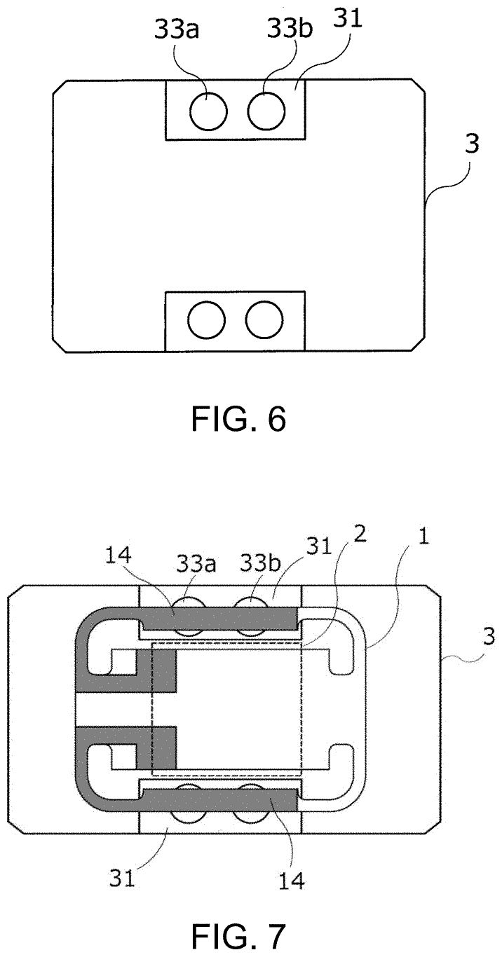

As illustrated in FIG. 5, while the conductive adhesive 32 slightly expands after the pedestal 1 is mounted, there is a part to which the conductive adhesive 32 is not applied between the metal pattern 31 and the connection portion 14 of the pedestal 1.

[Adhesion at Two Points on Each Side: FIG. 6 and FIG. 7]

FIG. 6 is an explanatory drawing illustrating an application pattern of an adhesion at two points on each side. FIG. 7 is an explanatory drawing illustrating a front surface of the quartz crystal device formed by the adhesion at two points on each side.

As illustrated in FIG. 6, in a case of the adhesion at two points on each side, conductive adhesives 33a and 33b are applied to two points on the metal pattern 31.

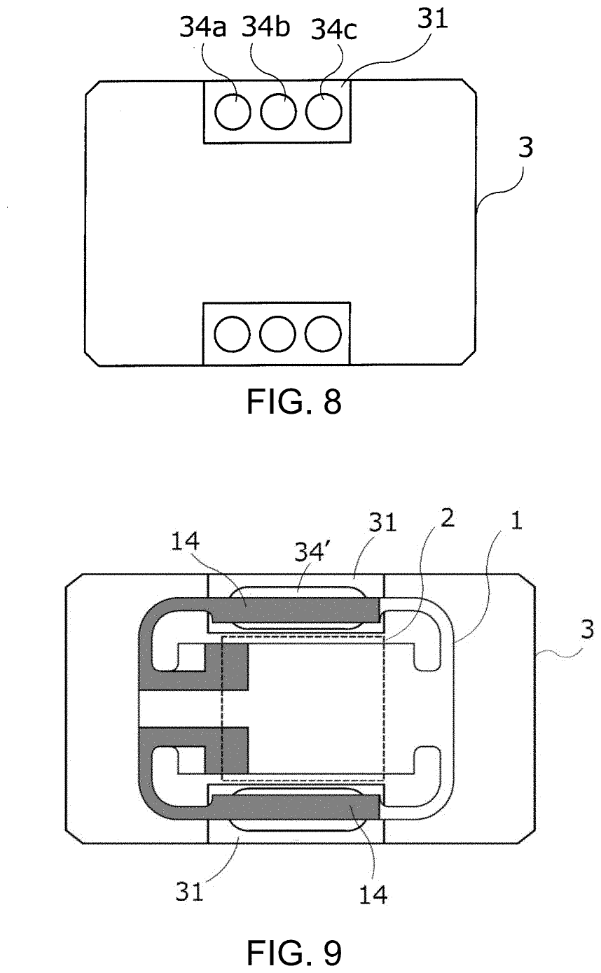

As illustrated in FIG. 7, even when the pedestal 1 is mounted, the conductive adhesives 33a and 33b are still arranged to be separated, and similarly to FIG. 5, there is a part to which the conductive adhesives 33 (33a and 33b) are not applied between the metal pattern 31 and the connection portion 14 of the pedestal 1.

[Adhesion at Three Points on Each Side: FIG. 8 and FIG. 9]

FIG. 8 is an explanatory drawing illustrating an application pattern of an adhesion at three points on each side. FIG. 9 is an explanatory drawing illustrating a front surface of the quartz crystal device formed by the adhesion at three points on each side.

As illustrated in FIG. 8, in the adhesion at three points on each side, conductive adhesives 34a, 34b, and 34c are applied to three points on the metal pattern 31.

As illustrated in FIG. 9, mounting the pedestal 1 onto the conductive adhesives 34a, 34b, and 34c presses the conductive adhesives 34a, 34b, and 34c from above to be flat, so as to be in contact with one another and integrated. This forms a lump of conductive adhesive 34′.

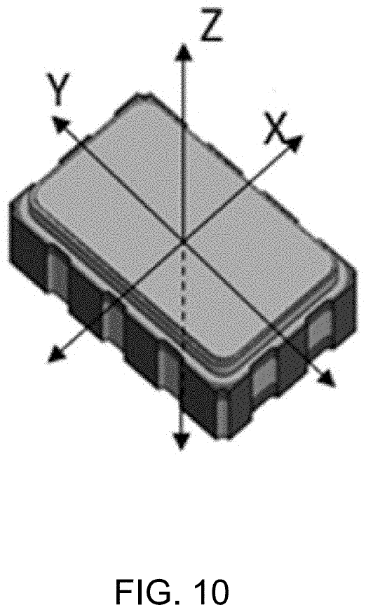

As illustrated in FIG. 9, it is seen that the metal pattern 31 and the connection portion 14 of the pedestal 1 are bonded with the conductive adhesive having a sufficient amount. The quartz crystal device illustrated in FIG. 9 is the quartz crystal device.

[Evaluation of Vibration Resistance Characteristic: FIG. 10]

Next, an evaluation of a vibration resistance of the quartz crystal device is described using FIG. 10. FIG. 10 is an explanatory drawing illustrating vibration directions used for evaluating vibration resistance characteristics.

Here, for the quartz crystal device to which the conductive adhesive was applied in the above-described three application patterns to be adhered to the base plate, as illustrated in FIG. 10, vibrations were applied in three directions of x, y, and z to obtain G-sensitivities as the vibration resistance characteristics. Their vibration acceleration is set to 2 G, and sine wave vibrations are set to 5 to 2000 Hz (simple harmonic motion of 10, 100, 500, 1000, and 2000 Hz).

[Calculation of G-sensitivity of Sine Wave Vibration]

A calculation of the G-sensitivity of the sine wave vibration is briefly described.

The G-sensitivities (ppb/g) in the respective vibration directions are obtained by Formula (1).

$$\begin{matrix}[ Math . 1 ] & \\ G = \frac{2 {F}_{V} \cdot {10}^{\frac{SSB}{20}}}{A \cdot {F}_{O}} & ( Formula 1 )\end{matrix}$$

Here, F_{V} is a vibration frequency (Hz), SSB is a spurious value (dBc) at a time of vibration, A is a vibration acceleration (g), and F_{O} is a nominal frequency (Hz).

Then, based on G-sensitivity values in the three directions of x, y, and z, a G-sensitivity value of the quartz crystal device is calculated by using Formula (2).

[Math. 2]

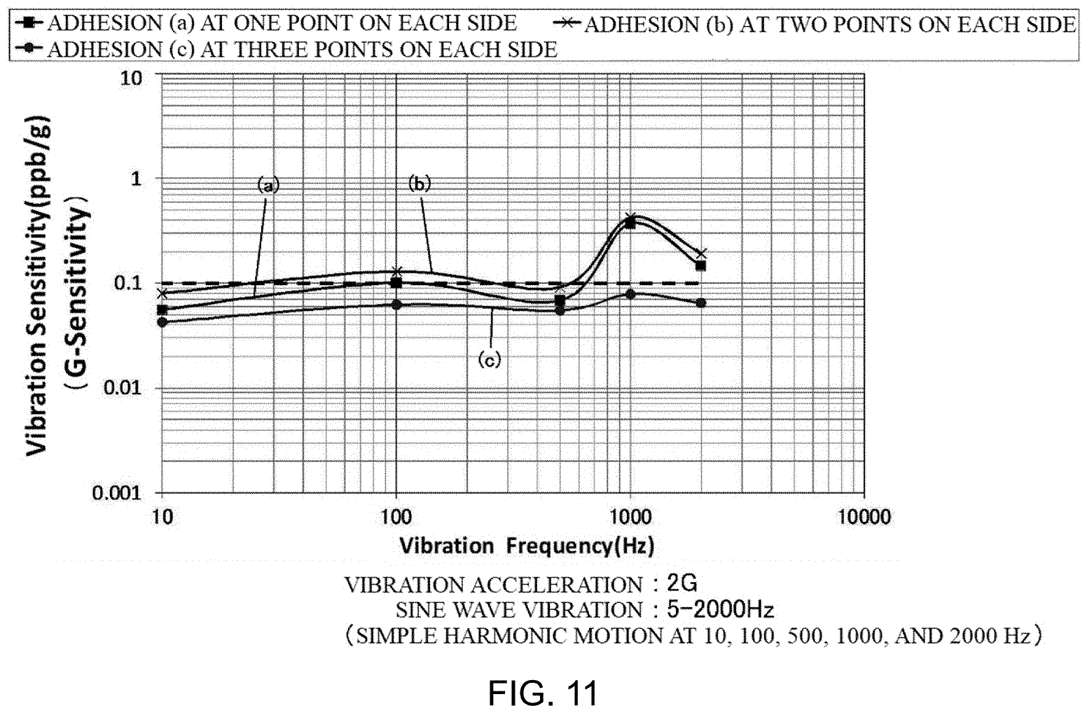

Γ=\sqrt{G_{X}²+G_{Y}²+G_{Z}²} (Formula 2)

[Evaluation Results of Vibration Resistance Characteristic: FIG. 11]

Evaluation results of the vibration resistance characteristic are described using FIG. 11. FIG. 11 is a diagram illustrating the evaluation results of the vibration resistance characteristic. In FIG. 11, Line (a) illustrates a case of the adhesion at one point on each side, Line (b) illustrates a case of the adhesion at two points on each side, and Line (c) illustrates a case of the adhesion at three points on each side.

The dashed line at the center is a reference value, and falling below the reference value indicates an excellent vibration resistance characteristic.

As illustrated in FIG. 11, comparing the vibration resistance characteristics of the quartz crystal devices produced by using the three types of the application patterns, it is seen that the quartz crystal device of Line (c) with the adhesion at three points on each side has the most excellent vibration resistance characteristic.

This is because it is conceivable as follows. The conductive adhesive 34′ is made of a soft material to function as a buffer having a cushioning property, and further, as also illustrated in FIG. 9, in the case of adhering to the three points, the conductive adhesive 34′ having a sufficient thickness exists between the connection portion 14 of the pedestal 1 and the metal pattern 31 of the base plate 3, and thus a vibration absorption property is superior to those of the other application patterns.

This causes the quartz crystal device to much more easily absorb the vibration by not only the vibration absorption effect by the pedestal 1 but also the damper effect by the integrated conductive adhesive 34′ to lead to the high vibration resistance characteristic.

[Application Amount of Conductive Adhesive]

Further, an application amount of the conductive adhesive was evaluated in the case of the adhesion at three points on each side.

Dimensions (diameter and height) of the conductive adhesive applied to the base plate 3 in an approximately hemispherical shape were changed to compare the vibration resistance characteristics of the quartz crystal devices.

Consequently, when the pedestal 1 having the above-described dimensions is bonded to the base plate 3, and when the conductive adhesives 34a, 34b, and 34c applied in hemispherical shapes have a diameter of 0.18 mm and a height of 20 μm, and the conductive adhesive 34′ after bonding to the pedestal 1 has a thickness of around 10 μm, thus obtained the excellent vibration resistance characteristic.

An excess application amount of the conductive adhesive deteriorates the aging characteristic due to its outgas.

Therefore, it is necessary that the connection portion 14 of the pedestal 1 has appropriate dimensions such that the three points are arranged to be separated and the three points are continuously integrated after bonding to the pedestal 1 to have a sufficient thickness when the conductive adhesives 34a, 34b, and 34c having the above-described dimensions are applied on the metal pattern 31.

Comparing a polyimide-based adhesive and the silicone-based adhesive, the silicone-based adhesive has a more excellent vibration resistance characteristic, and thus it is preferred to use the silicone-based adhesive. It is considered that this is because the silicone-based adhesive is more elastic.

### Effects of Embodiment

The quartz crystal device according to the embodiment of the disclosure is configured such that the crystal element 2 is mounted to the pedestal 1 configured to easily absorb a vibration, and the electrodes of the connection portion 14 that are disposed along a long side of the pedestal 1 are connected to the base plate 3 of the package made of, for example, ceramic with the conductive adhesive. After the conductive adhesives 34 (34a, 34b, and 34c) are dispersedly (dividedly) applied to a plurality of positions on the metal pattern 31 of the base plate 3, the electrodes of the connection portion 14 of the pedestal 1 and the electrodes of the base plate 3 are connected in the state where the respective portions are continuously integrated (conductive adhesive 34′). The pedestal 1 absorbs a vibration from outside. Additionally, increase of the application amount of the soft conductive adhesive 34 functions as a buffer between the pedestal 1 and the base plate 3 to provide the damper effect, and therefore the quartz crystal device provides the effect that further improves the vibration resistance characteristic to ensure the excellent phase noise characteristic.

Further, the method for manufacturing the quartz crystal device according to the embodiment of the disclosure is configured such that after the crystal element 2 is mounted to the pedestal 1 configured to easily absorb a vibration, and the conductive adhesive 34 is dividedly applied to a plurality of positions on the metal pattern 31 formed on the base plate 3 of the package made of, for example, ceramic, the pedestal 1 is mounted onto the metal pattern 31 to integrate the divided conductive adhesives 34, and the connection portion 14 of the pedestal 1 and the metal pattern 31 are adhered with the integrated conductive adhesive 34′. The pedestal 1 absorbs a vibration from outside. In addition to this, increase of the application amount of the soft conductive adhesive 34 provides the damper effect, and therefore the method provides the effect that further improves the vibration resistance characteristic to ensure the excellent phase noise characteristic.

The disclosure is appropriate for a quartz crystal device and a method for manufacturing the same. The quartz crystal device reduces the vibration influence from outside to improve the vibration resistance characteristic, thus ensuring the excellent phase noise characteristic.

Further, according to the disclosure, in the above-described quartz crystal device, the conductive adhesive dividedly applied to the plurality of positions may have a thickness of 10 μm or more and 30 μm or less.

Further, according to the disclosure, in the above-described quartz crystal device, the conductive adhesive dividedly applied to the plurality of positions may have a diameter of 0.10 mm or more and 0.25 mm or less.

Further, according to the disclosure, in the above-described quartz crystal device, the conductive adhesive may be a silicone-based adhesive.

Further, according to the disclosure, a method for manufacturing a quartz crystal device may include: mounting a crystal element to a pedestal, the pedestal including a main body, two connection portions that are formed along long sides of the main body and contact a base plate of a package, two clearance portions formed along the long sides inside the main body with respect to the connection portions, a mounting portion to which the crystal element is mounted, and arm portions formed on four corners of the main body to connect the mounting portion to the connection portions, the mounting portion being located between the two clearance portions; and adhering the connection portion of the pedestal and a metal pattern by applying a conductive adhesive dividedly to a plurality of positions on the metal pattern of the package to mount the connection portions of the pedestal onto the conductive adhesives, so as to integrate the plurality of divided conductive adhesives.

According to the disclosure, the quartz crystal device includes the pedestal to which the crystal element is mounted, and the pedestal is adhered to the metal pattern formed on the base plate of the package with the conductive adhesive. The pedestal includes the two connection portions that are formed along the long sides of the main body and contact the base plate, the two clearance portions formed along the long sides inside the main body with respect to the connection portions, the mounting portion to which the crystal element is mounted, and the arm portions formed on the four corners of the main body to connect the mounting portion to the connection portions. The mounting portion is located between the two clearance portions. The connection portion of the pedestal and the metal pattern are adhered in the state of being integrated after the conductive adhesive is dividedly applied to the plurality of positions on the metal pattern of the base plate. Therefore, since the conductive adhesive operates as a buffer between the base plate and the pedestal to absorb the vibration, in addition to the vibration absorption by the pedestal, the quartz crystal device provides the effect that further improves the vibration resistance characteristic to ensure the excellent phase noise characteristic.

Further, according to the disclosure, the method for manufacturing the quartz crystal device includes mounting the crystal element to the pedestal, and adhering the connection portion of the pedestal and the metal pattern by applying the conductive adhesive dividedly to the plurality of positions on the metal pattern of the package to mount the connection portions of the pedestal onto the conductive adhesives, so as to integrate the plurality of divided conductive adhesives. The pedestal includes the two connection portions that are formed along the long sides of the main body and contact the base plate of the package, the two clearance portions formed along the long sides inside the main body with respect to the connection portions, the mounting portion to which the crystal element is mounted, and the arm portions formed on the four corners of the main body to connect the mounting portion to the connection portions. The mounting portion is located between the two clearance portions. Therefore, since the conductive adhesive operates as a buffer between the base plate and the pedestal to ensure absorbing the vibration, in addition to the vibration absorption by the pedestal, the method provides the effect that ensures manufacturing the quartz crystal device having the further improved vibration resistance characteristic and the excellent phase noise characteristic.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A quartz crystal device comprising
a package that includes a base plate on which a metal pattern is provided; and
a pedestal to which a crystal element is mounted, the pedestal being adhered to the metal pattern with a conductive adhesive,
wherein the pedestal includes:
a main body;
two connection portions that are provided along long sides of the main body and contact the base plate;
two clearance portions provided along the long sides inside the main body with respect to the connection portions;
a mounting portion to which the crystal element is mounted, the mounting portion being located between the two clearance portions; and
arm portions provided on four corners of the main body to connect the mounting portion to the connection portions,
wherein the connection portion of the pedestal and the metal pattern are adhered with the conductive adhesive dividedly applied to a plurality of positions on the metal pattern of the base plate and subsequently integrated.

2. The quartz crystal device according to claim 1, wherein
the conductive adhesive dividedly applied to the plurality of positions has a thickness of 10 μm or more and 30 μm or less.

3. The quartz crystal device according to claim 1, wherein
the conductive adhesive dividedly applied to the plurality of positions has a diameter of 0.10 mm or more and 0.25 mm or less.

4. The quartz crystal device according to claim 1, wherein
the conductive adhesive is a silicone-based adhesive.

5. A method for manufacturing a quartz crystal device, comprising:
mounting a crystal element to a pedestal, the pedestal including:
a main body,
two connection portions that are formed along long sides of the main body and contact a base plate of a package,
two clearance portions formed along the long sides inside the main body with respect to the connection portions,
a mounting portion to which the crystal element is mounted, and
arm portions formed on four corners of the main body to connect the mounting portion to the connection portions, the mounting portion being located between the two clearance portions; and
adhering the connection portion of the pedestal and a metal pattern by applying a conductive adhesive dividedly to a plurality of positions on the metal pattern of the package to mount the connection portions of the pedestal onto the conductive adhesives, so as to integrate the plurality of divided conductive adhesives.
